(19) United States
(12) Patent Application Publication
(10) Pub. No.: US 2024/0284807 A1
(43) Pub. Date: Aug. 22, 2024

(54) A SAMPLE HOLDER AND A METHOD OF OPERATING IT

(71) Applicant: QDEVIL APS, Copenhagen O (DK)

(72) Inventors: Soren ANDRESEN, Copenhagen O (DK); Peter Ulrik KANN, Copenhagen O (DK); Merlin VON SOOSTEN, Copenhagen O (DK)

(21) Appl. No.: 18/573,683

(22) PCT Filed: May 23, 2022
(86) PCT No.: PCT/EP2022/063858

§ 371 Date: Dec. 22, 2023

(30) Foreign Application Priority Data
Jul. 2, 2021 (EP) 21183389.2

(51) Int. Cl. H10N 60/81; H10N 60/01

(52) U.S. Cl. CPC H10N 60/81; H10N 60/01

(57) ABSTRACT

A sample holder for a quantum device, the sample holder comprising a first portion comprising a first cavity, a second portion comprising a second cavity, first fixing elements comprising a printed circuit board comprising one or more electrical conductor(s) and/or wave guide(s), and second fixing elements configured to fix the first and second portions to each other, wherein the quantum device is provided over and covering at least part of the first cavity, the quantum device is provided over and covering at least part of the second cavity, the quantum device is fixed to the first portion by the first fixing elements and the electrical conductor(s) and/or wave guide(s) is/are connected to the quantum device and extend to outside of the first and second portions.

The present invention relates to a sample holder and more particularly a sample holder for a cryogenic quantum device, which sample holder is simple to mount the quantum device inside while providing the protection and cooling required by the quantum device.

A sample holder may be seen in e.g. “Microwave Packaging for Superconducting Qubits”, Lienhard et al., 12 Jun. 2019, MIT, (https://arxiv.org/abs/1906.05425) also presented in “Microwave Package Design for Superconducting Quantum Processors”, Huang et al., 16 Apr. 2021, MIT, PRX QUANTUM 2, 020306. Other relevant technology may be seen in US2020/100357 and “Broadband sample holder for microwave spectroscopy of superconducting qubits”, by Averkin A S et al, Review of Scientific instruments, vol. 85, 104702, 8/10 2014.

In a first aspect, the present invention relates to an assembly of a quantum device and a sample holder, the sample holder comprising:
a first portion comprising a first cavity,
a second portion comprising a second cavity,
first fixing elements comprising a printed circuit board configured to bias the quantum device toward the first portion, the printed circuit board comprising electrically conducting elements and/or wave guides of the printed circuit board, and
one or more electrical conductor(s) and/or wave guide(s) and
second fixing elements configured to fix the first and second portions to each other, wherein:
the quantum device covers at least part of the first cavity,
the quantum device covers at least part of the second cavity,
the quantum device is fixed to the first portion by the first fixing elements and
the electrical conductor(s) and/or wave guide(s) is/are connected to the quantum device and extend to outside of the first and second portions.

In this connect, an assembly comprises a number of individual elements which may or may not be fixed to each other. Each element of the assembly may itself be monolithic or a combination of a number of elements.

A quantum device may be any type of device, often a device for use under cryogenic conditions, which may be used in relation to e.g. quantum computers. A quantum device may comprise one or more qubits, either based on superconducting junction devices embedded in one or more microwave transmission lines, single electron charging devices coupled to microwave resonators and other device concepts relying on read-out of quantum information by coupling to a microwave transmission line.

The first portion may comprise a first surface in which the first cavity is provided or from which the first cavity extends. The second portion may comprise a second surface in which the second cavity is provided or from which the second cavity extends. When the first and second portions are fixed to each other, they may be positioned with the first surface and the second surface facing each other.

The first cavity may have an opening defining a first contour, and the second cavity may have an opening defining a second contour. When the first and second portions are fixed to each other, the first and second contours may overlap, such as when projected on to a predetermined plane, such as a plane extending between the first and second portions.

The second fixing elements may be any type of fixing elements, such as screws, bolts, clamps, glue, adhesive, welds, soldering, springs, resilient elements or the like. It may be desired that the second fixing elements also perform other tasks, such as thermal transport, so bolts/screws/clamps may be preferred.

The first fixing elements fix the quantum device in relation to the first portion. These fixing elements comprise a printed circuit board comprising the electrical conductor(s) and/or wave guide(s). The fixing elements may have additional tasks as will be described below.

Electrical connection between the electrically conducting elements and/or wave guides of the printed circuit board and electrically conducting elements and/or waveguides of the quantum device may be obtained in a number of manners. In one situation, the electrical connections are provided using soldering or wire bonding between the elements/waveguides of the PCB and quantum device, such as after fixing the quantum device in relation to the PCB.

Alternatively, resilient elements may be provided between the elements/waveguides of the PCB and those of the quantum device. Resilient elements may be springs, deformable elements, such as of a soft or resilient material. When it is desired that the resilient elements are electrically conducting, such as when used for interconnecting e.g. an electrically conducting element of the PCB with one of the quantum device, it may be made of an electrically conducting elements. Springs may be made of most electrically conducting materials. Resilient elements may be made from e.g. foams of or comprising electrical conductors. Some materials may in themselves be sufficiently resilient to be used as solid portions, such as drops or pellets, capable of being deformed to perform the interconnection desired. Such soft or resilient electrical conducting materials may, for example, be:
Soft metals as indium, lead or tin
Compliant insulators such as polymers or silicones with metallic elements incorporated
Compliant insulators such as polymers or silicones, doped (chemical) or filled (physical) to establish sufficient conductivity and/or
Conductive synthetic polymers or silicones

When fixed in relation to the first portion, the quantum device covers at least part of the first cavity. The quantum device may be positioned or provided over the first cavity. In this context, the quantum device may have a predetermined outline, when projected to the above plane, inside which at least a portion of the outline of the first contour is provided. It may be desired that at least an active portion or circuit or elements of the quantum device are provided squarely within the first contour in that plane, as they will then be better able to interfere with, detect, receive, emit, output or the like electromagnetic radiation provided in the cavity. The situation is the same in relation to the second cavity.

In addition, when the first and second portions are fixed to each other, the quantum device is provided over and covering at least part of the second cavity. The same considerations are applicable in relation to the second cavity.

In this context, it may be desired that the device is fixed to the first portion at a surface of the portion defining a first plane. It may be desired that the first portion extends only on one side of that plane, so that the mounting or fixing of the device need not be performed in a deep cavity but at a surface where it may easily be mounted, fixed, connected to and the like.

Finally, the electrical conductor(s) and/or wave guide(s) is/are connected to the quantum device and extend to outside of the first and second portions. In this manner, electrical signals or electromagnetic waves, such as radiation, RF signals or microwaves, may be transported to/from the device and/or cavity/ies.

In one embodiment, the PCB is embodied as a flexible element configured to bias the quantum device toward the first portion. In this manner, the fixing may be provided using only friction. The biasing force may be tailored to the quantum device to ensure that the fixing is sufficient yet not exceeded also after a large temperature change.

The PCB may be a plane element configured to extend between the first and second portions. Thus, the PCB may comprise shielding elements configured to block electromagnetic waves or radiation from travelling inside the PCB from the cavities and to surroundings of the first and second portions. The PCB may have an outer contour, in the plane, inside of which part of or all of the first and/or second portion is provided.

The PCB may itself be biased toward the first portion or attached thereto, such as using screws/bolts, glue, adhesives or the like.

In one embodiment, the assembly further comprises a cut-out portion at the first cavity, such as surrounding the first cavity, the quantum device being provided in the cut-out portion. In this manner, the device may be at least partly fixed in its position by edges of the cut-out portion. The portion may have a contour matching or only slightly larger than that of the device. To allow the device to be received therein. It may be preferred that the cut-out portion has a first depth and the quantum device, such as outer portions thereof received in the cut-out portion, have a first height, where the first height exceeds the first depth. It may be desired that the first height is between 150% and 100% of the first depth, so that up to 33% of the device height, such as up to 20%, such as up to 10%, such as up to 5%, extends outside of the cut-out portion.

The portion of the device extending out of the cut-out portion may be engaged by the first fixing elements, such as in the form of the above flexible PCB for obtaining the biasing. The first fixing elements may be biased toward a surface of the first portion, such as at the first surface, having the cut-out portion and the cavity. Then, due to the portion of the device extending out of the cut-out portion, a biassing may be applied of the corresponding portions of the device in a direction into or toward the cut-out portions.

Another manner of obtaining the same effect would be if the PCB had a cut-out or by providing an element, such as a washer-type element, at the first cut-out, the element having a suitable hole and a thickness corresponding to the desired cut-out. Also, a cut-out could be made in outer parts of the quantum device. Naturally any combination of these solutions would work.

It may be desired that only outer portions of the device are engaged by the first fixing means in order to e.g. allow more central portions to be exposed to e.g. radiation in the cavity.

The wave guides and/or electrically conducting elements may be provided on a surface of and/or inside the printed circuit board. The circuit board may comprise a base material, such as a polymer, ceramic or composite, which is not electrically conducting on which or inside which one or more electrically conducting elements and/or wave guides are provided. Conducting elements or wave guides may be provided on a surface of a base material and covered by another material, such as to avoid emission of radiation, noise or waves and/or avoid short circuiting when contacting with other elements, such as electrically conducting elements.

The electrically conducting elements and/or wave guides preferably extend from the device, such as inside the cavity/cavities, and to outside of the first and second portions. Thus, outside equipment, such as wave or signal generators and/or wave or signal detectors may be coupled, via the electrically conducting elements and/or wave guides to the device, such as for operation, test or the like.

In one embodiment, the assembly further comprises an electromagnetic shielding surrounding a main portion of the first and second portions. A suitable shielding may be of a superconducting material. Openings may be made in the material to e.g. transfer electrical signals and/or waves to/from the electrical conductor(s) and/or wave guide(s). Openings may also be provided for cooling the assembly and/or fixing or supporting the assembly.

It may be preferred that the assembly is cooled to a temperature below 100K, such as below 50K, such as below 10K, such as below 1K. This may be desired for or required for the device to operate as desired.

Another aspect of the invention relates to a method of mounting a quantum device in an assembly according to the first aspect of the invention, the method comprising:
a) fixing the quantum device to the first portion so as to cover at least a portion of the first cavity,
b) fixing the second portion to the first portion so that the quantum device covers at least a portion of the second cavity, and
c) electrically connecting the quantum device to the electrically conducting element(s) and/or wave guide(s) which preferably extend to outside of the first and second portions to the quantum device.

Naturally, all embodiments, situations and considerations described above are equally valid for the present aspect of the invention.

Also, if electrical connection is desired to the device, this may be handled before step c).

Thus, step a) may be performed before step b), so that the quantum device may be fixed to the first portion without the second portion being in the way. Having fixed the quantum device to the first portion and potentially provided the electrical and/or wave connections, the second portion may be fixed to the first portion in order to assemble the assembly and enclose the device in the common cavity. The common cavity may be formed by inner surface of the first and second cavities but also additional elements, such as the above-mentioned cut-out portions, the first fixing elements and the like.

In one embodiment, step a) comprises biasing, via the PCB, which may be a flexible element, the quantum device toward the first portion. The PCB may then be fixed to, adhered to or biased toward the first portion and may then itself bias the quantum device toward the first portion to prevent the device from displacing vis-à-vis the first portion.

As described above, step c) comprises electrically connecting the quantum device to the electrically conducting element(s) and/or wave guides. As explained above, the conducting elements and/or wave guides extend to outside of first and second elements to allow easy connection thereto.

In one embodiment, the first portion comprises a cut-out portion at the first cavity, wherein step a) comprises providing the quantum device in the cut-out portion. Subsequently, the fixing or biassing may be performed to prevent the device from leaving the cut-out portion.

In one situation, the cut-out portions have a first depth and the quantum device, such as outer portions thereof, have a first height, where the first height exceeds the first depth. This is explained above.

It may be desired to provide an electromagnetic shielding, preferably of a superconducting material, surrounding at least a main portion of the first and second portions. Openings may be provided in the shield, such as for contacting the electrically conducting elements and/or wave guides as well as for engaging the assembly for fixing or cooling it.

As explained, it may be preferred to cool the assembly to a temperature below 100K.

In the following, preferred embodiments are described with reference to the drawing, wherein:

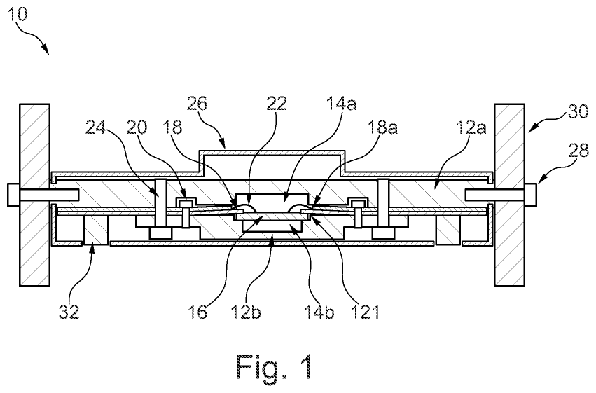

FIG. 1 illustrates a cross section through a preferred sample holder according to the invention,

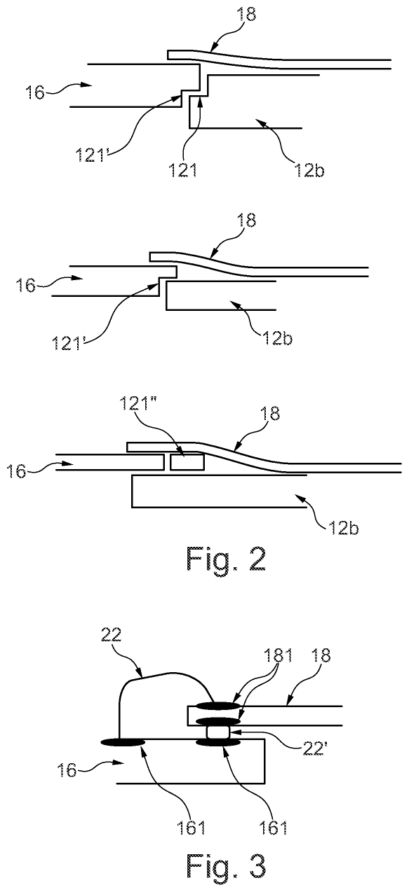

FIG. 2 illustrates different cut-out types and

FIG. 3 illustrates different manners of connecting conducting elements.

In FIG. 1, a sample holder 10 is illustrated generally comprising an upper portion 12a and a lower portion 12b. The lower portion 12b has a cavity 14b over which a quantum device 16 is provided. The device 16 is provided in a cut-out portion 121 which may delimit movement of the device in a direction in a plane of the device. The device 16 is biased downward by a PCB, 18 clamped to the lower element 12b by screws 20.

The PCB comprises conducting portions which may be connected to the device either by the direct connection between the device and PCB or via other manners such as wire bonds 22. Wire bonds 22 are especially useful when the connection portions are provided on surfaces facing at least generally in the same direction and which are exposed. When the connection portions are provided on surfaces facing each other, these may overlap, so that electrically conducting, resilient elements may be provided between the PCB and the quantum device and more particularly between pairs of a conductor or connection portion of the quantum device and one of the PCB. Such resilient elements may be springs or balls/drops, such as made from any conducting material, such as metals or any of the above-mentioned materials, which may be fixed to one of the PCB and the quantum device before assembly if desired.

The device may be biased toward the lower portion 12b by a biassing provided by the PCB 18. In this manner, the device may be fixed in a position without exerting a too large force on to it. The PCB may be selected or dimensioned to provide the biasing desired.

Also, the height or depth of the cut-out or indentation 121 may be selected only slightly lower than a height of the quantum device, such as outer portions of the quantum device 16, so that the PCB needs flex only slightly to provide the desired biasing.

Then, the device 16 is positioned in a combined cavity which may be used for e.g. providing microwaves to and/or receiving microwaves from the device, such as for affecting or reading-out one or more cubits on the device. The flexible element may comprise microwave antennas, microwave guides, RF antennas and/or RF conductors in order to provide such radiation to and/or remove such radiation from the device or cavity.

Thus, the electrical contacting to the device may be used for testing the device and/or operating the device. The testing may comprise feeding signals to the device and receiving signal therefrom for later analysis to derive information from or relating to the device.

The upper and lower portions are bolted to each other using bolts 24. In this manner, the upper and lower portions form a sealed space or cavity holding the device.

Electrical contacting from the outside of the assembly may be achieved via contacts or connectors 32 extending away from the PCB 18. Connectors 32 may be for electrical contacting, coaxial feeding and/or RF or microwave signals and may be achieved via connectors mounted to the PCB 18.

The PCB 18 may have on a surface thereof electrically conducting portions or traces. To prevent contact with the element 12a, another element, 18a, may be provided, which is not electrically conducting. As illustrated, the element 18a allows the PCB 18 to be exposed and contactable at the portion closest to the device 16. This contacting may be by wire bonding or direct physical contact, or contact via soldering, welding, electrically conducting glue or the like, between conductors of the PCB and of the device. It may be preferred that only the PCB 18 extends over the device so as to bias it. Alternatively, also the element 18a may be used for this purpose, such as if the PCB itself is not able to provide a sufficient biasing force.

The upper and lower portions as well as the bolts 24 may be selected to allow efficient cooling from outside of the assembly, such as a cryogenic interface 30, to the cavity and the device, as in a preferred embodiment, the device is a quantum device for operations at temperatures below 100K, such as below 10K, such as below 1K.

Especially in such situations, the assembly may further comprise a superconducting EMC shield 26 is placed all around the assembly to further shield out any microwave background from reaching into the cavity.

FIG. 2 illustrates portions of the lower portion 12b, the device 16 and the PCB 18 in different embodiments where, in the upper illustration, both the device 16 and the lower portion 12b have cut-outs, 121′ and 121, respectively. In the middle illustration, the device 16 has a cutout 121′, and in the lower illustration, no cut-outs are provided. Instead, a washer 121″ is provided which may be fixed to the lower portion 12b to thereby guide or control the device 16 in the same manner as the cut-outs.

In FIG. 3, different manners of electrically connecting the PCB 18 and eth device 16 are provided. As described in relation to FIG. 1, wire bonds 22 may be used between electrically conducting elements or wave guides 181 of the PCB 18 and 161 of the device 16. This is the easiest if the surfaces on which the elements/guides 181 and 161 are exposed and face in the same direction. If the elements/guides are provided on surfaces facing each other, these elements/guides may be positioned opposite to each other, so that electrically conducting elements 22′ may be positioned between the elements/guides 161/181 and thus provide the electrical contact. The electrical contact may be provided or increased if or when the PCB is biased toward the element 16.

Optimal performance of the design may be ensured by careful selection of materials and surface treatments:
1. The PCB 18 is constructed from low-loss dielectric material, e.g. PTFE or composites based thereon, with signal and ground layers made of either highly conductive copper and/or superconductive layers. The metal layers may be surface plated by either gold or superconductive metals to improve the electrical performance and avoid oxidation.
2. The upper and lower portions 12a/12b are made out of highly conductive metal, e.g. copper and/or alloys thereof. Surface plating by gold or other passivation is used to avoid oxidation and improve thermal contact. Superconducting surface plating of the cavity inner surfaces may be used to improve the electrical performance.
3. The bolts 24 that fix the portions to each other as well as any bolts 28 for mounting the assembly onto the cryogenic interface 30 are made from beryllium copper, ensuring efficient thermalization and also providing better mechanical strength than pure copper metal.
4. The superconducting EMC shields 26 on the outside of the package can be made from different superconducting materials, e.g. aluminium, niobium, titanium and/or alloys thereof. To ensure fully connected EMC shielding, the parts may be surface treated to avoid insulating oxides, e.g. by chrome passivation, zincate treatment or similar.

All ingoing parts are made from carefully selected non-magnetic metals and alloys to avoid stray magnetic fields that may disturb the performance of superconducting quantum devices. Furthermore, the whole package may be positioned in an external magnetic shielding consisting of both a superconducting can and a mu-metal enclosure. The superconductor will repel all magnetic fields by its inherent Meissner effect, whereas the mu-metal enclosure helps to avoid trapping of magnetic flux in the superconductor during cool-down.

All parts are designed with vent ports from all inner cavities 14a/14b to allow trapped air to escape to vacuum before cool-down. At the same time, no line-of-sight is allowed from the outside through both the superconducting EMC shielding and the frame parts that form the cavity. That would allow microwave background radiation to leak into the cavity. Therefore, also fully EMC tight superconducting flanges are used to seal off the connector fittings and the exposed ports around the screws for mounting onto the cryogenic interface.

1-11. (canceled)

12. An assembly of a quantum device and a sample holder, the sample holder comprising:
a first portion comprising a first cavity,
a second portion comprising a second cavity,
first fixing elements comprising a printed circuit board configured to bias the quantum device toward the first portion, the printed circuit board comprising electrically conducting elements and/or wave guides of the printed circuit board, and
second fixing elements configured to fix the first and second portions to each other, wherein:
the quantum device covers at least part of the first cavity,
the quantum device covers at least part of the second cavity,
the quantum device is fixed to the first portion by the first fixing elements, and
the electrical conductor(s) and/or wave guide(s) is/are connected to the quantum device and extend to outside of the first and second portions.

13. The assembly according to claim 12, further comprising a cut-out portion at the first cavity, the quantum device being provided in the cut-out portion.

14. The assembly according to claim 13, wherein the cut-out portions have a first depth, and the quantum device has a first height, where the first height exceeds the first depth.

15. The assembly according to claim 12, further comprising an electromagnetic shielding surrounding a main portion of the first and second portions.

16. The assembly according to claim 12, cooled to a temperature below 100K.

17. A method of mounting a quantum device in an assembly according to claim 12, the method comprising:
a) fixing the quantum device to the first portion so as to cover at least a portion of the first cavity,
b) fixing the second portion to the first portion so that the quantum device covers at least a portion of the second cavity, and
c) electrically connecting the quantum device to the electrically conducting element(s) and/or wave guide(s).

18. The method according to claim 17, wherein step a) comprises biasing, via the printed circuit board, the quantum device toward the first portion.

19. The method according to claim 17, wherein the first portion comprises a cut-out portion at the first cavity,
wherein step a) comprises providing the quantum device in the cut-out portion.

20. The method according to claim 19, wherein the cut-out portion has a first depth, and the quantum device has a first height, where the first height exceeds the first depth.

21. The method according to claim 17, further comprising the step of providing an electromagnetic shielding surrounding a main portion of the first and second portions.

22. The method according to claim 17, further comprising the step of cooling the assembly to a temperature below 100K.
